(19) United States
(12) Patent Application Publication
(10) Pub. No.: US 2009/0032887 A1
(43) Pub. Date: Feb. 5, 2009

(54) TRANSISTOR HAVING GATE ELECTRODE WITH CONTROLLED WORK FUNCTION AND MEMORY DEVICE HAVING THE SAME

(75) Inventors: Se-Aug Jang, Ichon-shi (KR); Hong-Seon Yang, Ichon-shi (KR); Heung-Jae Cho, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/163,403

(22) Filed: Jun. 27, 2008

(30) Foreign Application Priority Data
Jul. 31, 2007 (KR) 10-2007-0076932

(51) Int. Cl. H01L 29/00

(52) U.S. Cl. 257/407; 257/E29.001

(57) ABSTRACT

A transistor includes a gate insulation layer over a substrate, a gate line comprising electrodes each having a different work function on the gate insulation layer, and a source junction and a drain junction formed inside portions of the substrate on first and second sides of the gate line.

### CROSS-REFERENCE TO RELATED APPLICATIONS

The present invention claims priority of Korean patent application number 2007-0076932, filed on Jul. 31, 2007, which is incorporated by reference in its entirety.

### BACKGROUND OF THE INVENTION

The present invention relates to a method for fabricating a semiconductor memory device, and more particularly, to a method of fabricating transistors of a semiconductor memory device having gate electrodes with different work functions.

As a memory device becomes highly integrated, a two-dimensional transistor structure (which is called a planar transistor) reaches a limit in various aspects. Particularly, in a high speed device, a two-dimensional transistor structure cannot satisfy required high current drivability. To overcome this limitation, three-dimensional transistor such as a fin field effect transistor (EFT) (referred to as ‘fin transistor’ hereinafter) has been proposed.

The fin transistor uses three planes as channels, and consequently, provides excellent current drivability. However, since the channels (i.e., three planes) are easily opened, it has a limitation that a threshold voltage Vₜ is very difficult to raise to a predetermined level or more.

In general, a cell transistor of a memory device such as a dynamic random access memory (DRAM) uses an n-channel metal oxide semiconductor field effect transistor (nMOSFET). It is difficult to apply a fin transistor to a cell transistor requiring a high threshold voltage of 0.8 V or more. When a threshold voltage is not raised above a predetermined level in a DRAM, off-leakage current such as gate induced drain leakage (GIDL) increases.

Recently, as a method for easily raising a threshold voltage in a fin cell transistor of a memory device, a method of forming a gate electrode of a fin transistor using an In-Situ Boron doped P-type polysilicon layer (P⁺ poly Si) instead of an In-Situ Phosphorus doped N-type polysilicon layer (N⁺ poly Si) has been proposed. Theoretically, since the work function of the P⁺ poly Si is higher than that of the N⁺ poly Si by approximately 1.1 eV, merely replacing the gate electrode of the nMOSFET can raise the threshold voltage to a level of approximately 0.8 V to approximately 1.0 V.

FIG. 1 illustrates a cross-sectional view of a typical memory device having a fin FET.

Referring to FIG. 1, a device isolation layer 12 is formed in a substrate 11 including a cell region and a peripheral circuit region. An nMOSFET is formed in the cell region of the substrate 11, and an nMOSFET and a pMOSFET are formed in the peripheral circuit region of the substrate 11. The cell region is called a ‘cell nMOS region’, an nMOS region in the peripheral circuit region is called a ‘peripheral circuit nMOS region’, and a pMOS region in the peripheral circuit region is called a ‘peripheral circuit pMOS region’.

A fin structure 11A used as a channel is formed in the cell nMOS region, a gate insulation layer 13 is formed over the fin structure 11A, and a gate electrode 14A formed of P⁺ poly Si is formed over the gate insulation layer 13.

The peripheral circuit nMOS region becomes a planar transistor including a gate insulation layer 13 on the substrate 11, and a gate electrode 14B formed of an N-type polysilicon layer (N⁺ poly Si) on the gate insulation layer 13.

Also, the peripheral pMOS region becomes a planar transistor including a gate insulation layer 13 on the substrate 11, and a gate electrode 14A formed of a P-type polysilicon layer (P⁺ poly Si) on the gate insulation layer 13.

Generally, the threshold voltage Vₜ of a transistor is proportional to the work function φ of a material used for the gate electrode. That is, when the work function of the gate electrode is high, the threshold voltage can be raised.

FIGS. 2A and 2B explain a limitation when P-type polysilicon layer is used as a gate electrode in the cell nMOS region.

FIGS. 2A and 2B compare the band diagram of a case where a heavily-doped N-type polysilicon layer (N⁺ poly Si) whose work function is 4 eV (φ_{N}) is formed over the gate insulation layer 13 with the band diagram of a case where a heavily-doped P-type polysilicon layer (P⁺ poly Si) whose work function is 5 eV (φ_{P}) is formed over the gate insulation layer 13. It is assumed that both a source region and a drain region are a source/drain region N⁻ S/D doped with N-type impurities at lower concentration than the polysilicon layer for the gate electrode. Generally, the work function of the heavily-doped N-type polysilicon layer is slightly smaller than those of the lightly-doped N-type source and drain regions, and the work function of the P-type polysilicon layer is much larger than that of the lightly doped N-type polysilicon layer. Also, reference symbols ‘Eᵢ’, ‘E_{f}’, ‘E_{c}’, and ‘Eᵥ’ are energy levels, and VL is a vacuum level. Generally, a work function means a value between the vacuum level VL and a Fermi level E_{f}.

The results illustrated in FIGS. 2A and 2B are described. Since a difference in a work function between an N-type polysilicon layer and N-type source/drain regions is small in the case where the N-type polysilicon layer is used as a gate electrode, a band bending 20A almost does not occur. Since a difference in a work function between a P-type polysilicon layer and N-type source/drain regions is very large in the case where the P-type polysilicon layer is used as a gate electrode, a band bending 20B at a junction interface with the gate insulation layer excessively occurs.

Consequently, when a P-type polysilicon layer is used as a gate electrode in the cell nMOS region, a GIDL characteristic becomes very weak compared with the case of using an N-type polysilicon layer, so that data retention characteristic of a DRAM rapidly deteriorates.

GIDL increases in the case where a P-type polysilicon layer is used as a gate electrode because a band bending excessively occurs in an overlapping region of the gate electrode and a drain region and consequently electrons moves through tunneling from a valence band Eᵥ to a conduction band E_{c}. It is known that the GIDL increases even more when the band bending is serious. As revealed from FIGS. 2A and 2B, since the band bending occurs excessively in the case where a P-type polysilicon layer is used, the GIDL increases even more.

### SUMMARY OF THE INVENTION

Embodiments of the present invention relate to a transistor of a memory device having a gate electrode that has a threshold voltage raised to a predetermined level or more while having high current drivability and low gate induced drain leakage.

In accordance with an aspect of the present invention, there is provided a transistor including a gate insulation layer over a substrate, a gate line comprising electrodes each having a different work function on the gate insulation layer, and a source junction and a drain junction formed inside portions of the substrate on first and second sides of the gate line.

In accordance with another aspect of the present invention, there is provided a memory device including a substrate comprising a cell region and a peripheral circuit region, a gate insulation layer on the substrate, a first gate electrode formed over a portion of the gate insulation layer corresponding to the cell region, and a second gate electrode formed over a portion of the gate insulation layer corresponding to the peripheral circuit region, the first gate electrode comprising electrodes each having a different work function.

### BRIEF DESCRIPTION OF THE DRAWINGS

FIG. 1 illustrates a cross-sectional view of a typical memory device having a fin FET.

FIGS. 2A and 2B explain a limitation when P-type polysilicon layer is used as a gate electrode in the cell nMOS region.

FIG. 3A illustrates a structural cross-sectional view of a transistor in accordance with an embodiment of the present invention.

FIG. 3B illustrates a cross-sectional view of FIG. 3A, taken along a line A-A′.

FIG. 4A illustrates a cross-sectional view of a transistor in accordance with another embodiment of the present invention.

FIG. 4B illustrates a cross-sectional view of FIG. 4A, taken along a line A-A′.

FIG. 5 illustrates a cross-sectional view of a memory device in accordance with still another embodiment of the present invention.

FIGS. 6A to 6F illustrate cross-sectional views explaining a method for manufacturing a memory device illustrated in FIG. 5.

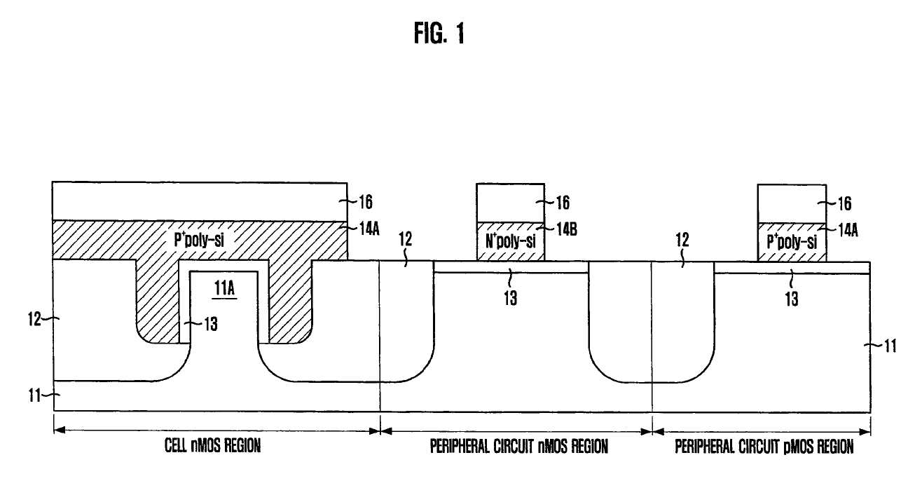

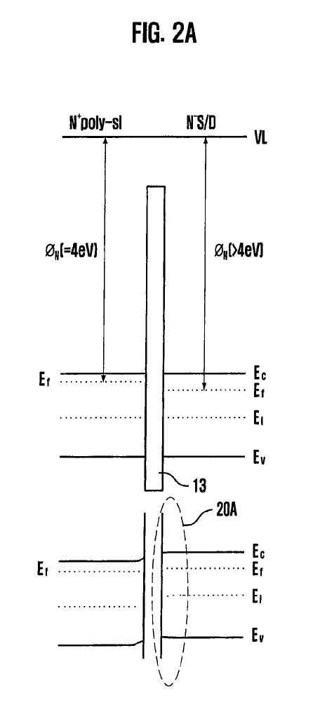

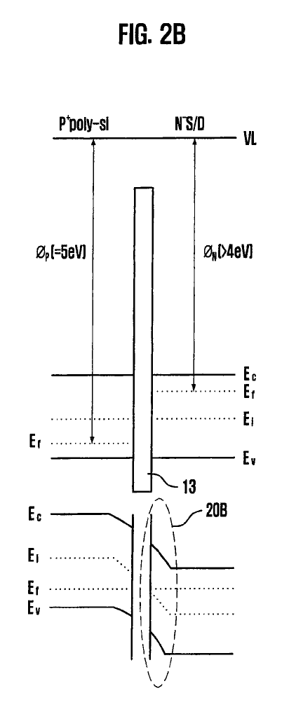

### DESCRIPTION OF SPECIFIC EMBODIMENTS

Embodiments of the present invention relate to a transistor of a memory device having a gate electrode with a controlled work function.

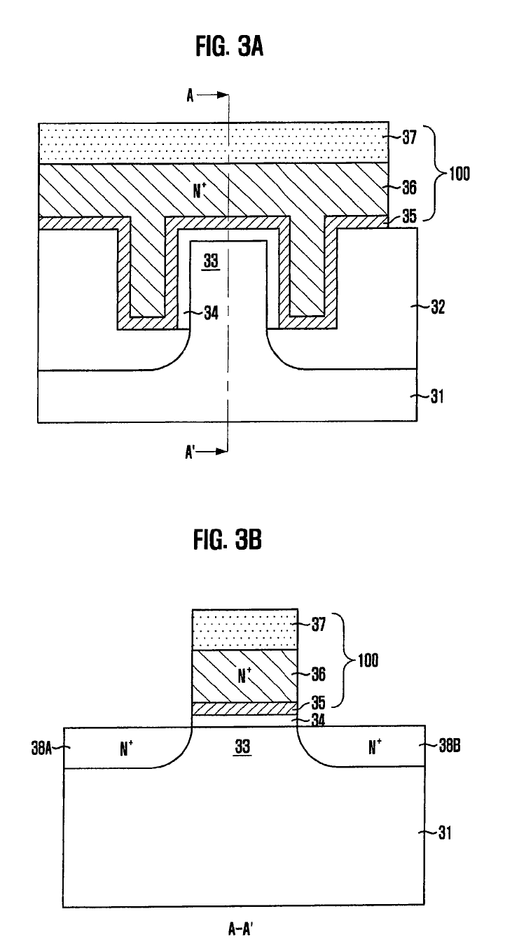

FIG. 3A illustrates a cross-sectional view of a transistor in accordance with an embodiment of the present invention.

Referring to FIG. 3A, a gate insulation layer 34 is formed over the substrate 31. Here, a device isolation layer 32 is formed over the substrate 31, and a fin structure is formed in the substrate 31. Here, the fin structure is an example of a multi-plane channel for increasing a channel length. The fin structure 33 is formed by partially recessing the device isolation layer 32. For forming the multi-plane channel, a recess, a saddle fin, and a bulb type recess structure can be formed besides the fin structure 33. The multi-plane channel structures lengthen a channel length compared to a general planar structure to obtain a transistor of high current drivability.

Also, a gate electrode 100 in which a first electrode 35, a second electrode 36, and a third electrode 37 are sequentially stacked is formed over the gate insulation layer 34. In the gate electrode 100, the first electrode 35 has a thickness of approximately 30 Å to approximately 150 Å, the second electrode 36 has a thickness of approximately 500 Å to approximately 100 Å, and the third electrode 37 is thicker than the first electrode 35 and thinner than the second electrode 36.

The gate electrode 100 is described below in more detail.

The first electrode 35 contacts the gate insulation layer 34, and the second electrode 36 is formed over the first electrode 35. Here, the work function of the first electrode 35 contacting the gate insulation layer 34 has a wider range than that of the second electrode 36.

For example, in the case where the second electrode 36 is a polysilicon layer, the first electrode 35 is a material having a higher work function than that of the polysilicon layer. On the other hand, in the case where the first electrode 35 is a metal layer, the second electrode 36 is a material having a smaller work function than that of the metal layer. Also, the first electrode 35 is a material having a work function smaller than that of a P-type polysilicon layer and greater than that of an N-type polysilicon layer.

Particularly, in the case where the second electrode 36 is a polysilicon layer, the first electrode 35 can be a metal layer. At this point, the second electrode 36 and the first electrode 35 may be an N-type polysilicon layer and a Titanium nitride (TiN) layer, respectively. The N-type polysilicon layer has a work function of approximately 4 eV, and the titanium nitride (TiN) layer has a work function in the range of approximately 4.4 eV to approximately 4.8 eV. The work function in the range of approximately 4.4 eV to approximately 4.8 eV is considered a mid work function, smaller than the work function (approximately 5 eV) of the P-type polysilicon layer and greater than the work function (approximately 4 eV) of the N-type polysilicon layer. The N-type polysilicon layer used as the second electrode 36 is doped with N-type impurities such as P and As.

As described above, when the first electrode 35 formed of a metal layer is directly formed over the gate insulation layer 34, an excessive band bending caused by use of a typical P-type polysilicon layer can be minimized. That is, the band bending is dominated by the first electrode 35, and the band bending is further suppressed at the interface with the metal layer in comparison with the case where an N-type polysilicon layer is used.

The third electrode 37 is a low resistance metal layer and is used to reduce sheet resistance of the gate electrode 100. For example, the third electrode 37 can be a tungsten layer or a tungsten silicide layer. When the sheet resistance is reduced, a high speed device operation can be achieved.

Meanwhile, a diffusion barrier layer can be further formed between the second electrode 36 and the third electrode 37. A gate hark mask can be further formed over the third electrode 37. The diffusion barrier layer serves as not only a diffusion barrier layer, preventing mutual diffusion between the second electrode 36 and the third electrode 37, but also a reaction prevention layer preventing the second electrode 36 and the third electrode 37 from reacting with each other. For example, the diffusion barrier layer can include a Ti layer, a stacked structure (TiN/WN) of a TiN layer and a WN layer, and a stacked structure (Ti/TiN/WN) of a Ti layer, a TiN layer, and a WN layer. Also, the gate hard mask layer makes a gate patterning process easy and protects the gate electrode in a subsequent contact process, and includes a nitride layer.

FIG. 3B illustrates a cross-sectional view of FIG. 3A, taken along a line A-A′.

Referring to FIG. 3B, a junction doped with impurities can be formed in portions of the substrate 31 on both sides of the gate electrode 100. For example, an N-type source region 38A and an N-type drain region 38B doped with N-type impurities are formed. The junction can be a source region and a drain region doped with P-type impurities. Here, the N-type source region 38A and the N-type drain region 38B can be heavily or lightly doped with N-type impurities.

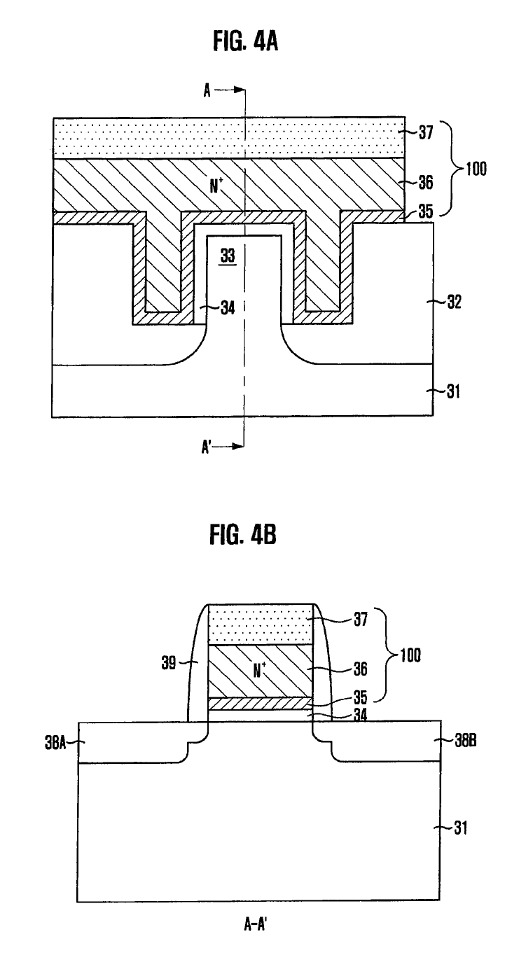

FIG. 4A illustrates a structural cross-sectional view of a transistor in accordance with another embodiment of the present invention, and FIG. 4B illustrates a cross-sectional view of FIG. 4A, taken along a line A-A′.

Referring to FIGS. 4A and 4B, the transistor in accordance with the another embodiment has a transistor structure in which gate sidewall spacers 39 are further provided on both sidewalls of the gate electrode 100 in the structure of the previous embodiment, so that an N-type source region 38A and an N-type drain region 38B having a lightly doped drain (LDD) structure 40 are formed. Here, the LDD 40 is a structure lightly doped with N-type impurities and the concentration of the N-type impurities is lower than those of the N-type source region and the N-type drain region. Generally, this LDD is denoted by ‘N⁻LDD’.

Meanwhile, a transistor structure in which an N-type source region 38A and an N-type drain region 38B having a source drain extension (SDE) structure besides the LDD 40 are formed can be applied. Here, the SDE structure is a structure heavily doped with N-type impurities. The SDE structure is formed by doping N-type impurities at the same concentration as the N-type source region and the N-type drain region, and has a lower junction depth than those of the N-type source region 38A and the N-type drain region 38B.

In accordance with the previous embodiments, the gate electrode 100 formed over the gate insulation layer 34 includes a first electrode 35 and a second electrode 36 each having a different work function.

Particularly, since the first electrode 35 is a metal layer and the second electrode 36 is an N-type polysilicon layer, the first electrode 35 and the second electrode 36 each has a different work function. The work function of the first electrode 35 is in the range of approximately 4.4 eV to approximately 4.8 eV, and the second electrode 36 is approximately 4 eV. That is, the work function of the first electrode 35 is greater than that of the second electrode 36.

As described above, since the second electrode 36 (formed of a polysilicon layer) exists over the first electrode 35 (formed of the metal layer), but the first electrode 35 (formed of the metal layer) directly contacts the gate insulation layer 34, the threshold voltage of the transistor is dominated by the work function of the first electrode 35. Since the work function of the first electrode 35 is smaller than a typical P-type polysilicon layer, a band bending does not occur excessively, and thus GIDL is reduced. Also, since the work function of the thin first electrode 35 is larger than that of an N-type polysilicon layer used as the second electrode 36, the threshold voltage of the transistor can be increased to a predetermined level or more.

Consequently, the metal layer having a smaller work function than that of the P-type polysilicon layer is allowed to contact the gate insulation layer 34 and thus to be included in the gate electrode 100, so that a high threshold voltage is obtained to reduce off-leakage, and simultaneously, a band bending at a junction interface with the gate insulation layer 34 can be smoothed.

Also, a multi-plane channel such as the fin structure 33 is applied to increase a channel length, so that current drivability can be improved.

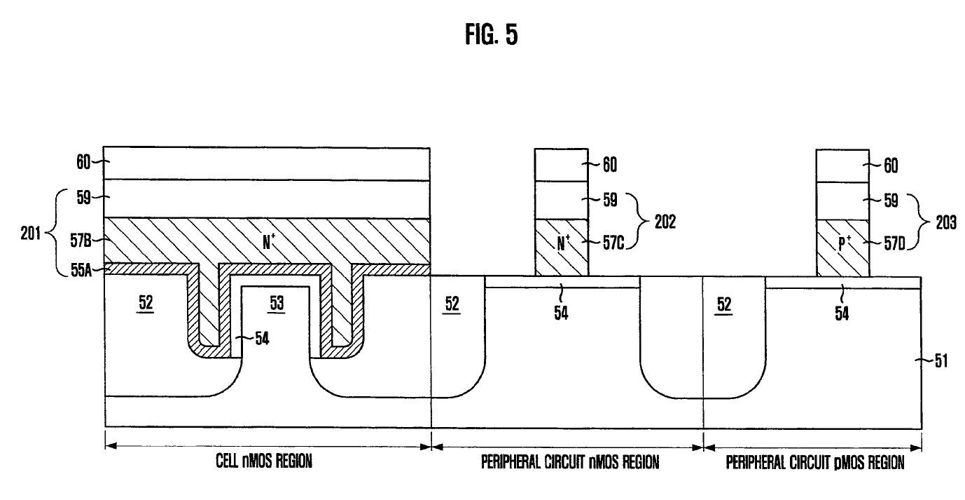

FIG. 5 illustrates a cross-sectional view of a memory device in accordance with still another embodiment of the present invention.

Referring to FIG. 5, a gate insulation layer 54 is formed over a substrate 51. Here, the substrate 51 is divided into a plurality of regions by a device isolation layer 52. Roughly, the substrate 51 is divided into a cell region and a peripheral circuit region. The peripheral circuit region is divided into an nMOS region and a pMOS region. Meanwhile, a cell region is an nMOS region where an nMOS is to be formed. Hereinafter, the cell region is called a ‘cell nMOS region’, the nMOS region in the peripheral circuit region is called a ‘peripheral circuit nMOS region’, and the pMOS region in the peripheral circuit region is called a ‘peripheral circuit pMOS region’.

Also, a portion of the substrate 51 in the cell nMOS region has a fin structure 53, and portions of the substrate 51 in the peripheral circuit nMOS region and pMOS region have a planar structure. Here, the planar structure is designed for a horizontal channel, and the fin structure 53 is designed for a multi-plane channel, increasing a channel length compared to the planar structure. Though the fin structure has been illustrated in FIG. 5, a recess, a saddle fin, and a bulb type recess structure can also be formed over a portion of the substrate 53 in the cell nMOS region. An nMOSFET formed in the cell nMOS region has a multi-plane channel using the above-described structures to create a longer channel length compared to that of the planar structure.

Also, gate electrodes 201, 202, and 203 each having a different work function are formed over the gate insulation layer 54 in respective regions.

The gate electrode 201 in the cell nMOS region includes a first metal layer 55A and an N-type polysilicon layer 57B. The gate electrode 202 in the peripheral circuit nMOS region includes an N-type polysilicon layer 57C. The gate electrode 203 in the peripheral circuit pMOS region includes a P-type polysilicon layer 57D. Meanwhile, the gate electrode in each region further includes a second metal layer 59 in an uppermost layer, and a gate hard mask layer 60 can be further formed over each gate electrode. A second metal layer 59 is a low resistance metal layer and is used to reduce the sheet resistance of the gate electrode. For example, the second metal layer 59 can be a tungsten layer or a tungsten silicide layer. Also, the gate hard mask layer 60 includes a nitride layer.

The N-type polysilicon layers 57B and 57C are polysilicon layers doped with N-type impurities such as P and As. The P-type polysilicon layers 57D is a polysilicon layer doped with P-type impurities such as B. The N-type and P-type polysilicon layers 57B, 57C, and 57D have a thickness of approximately 500 Å to approximately 1000 Å. As described later, the P-type polysilicon layer 57D is formed by counter-doping N-type impurity doped polysilicon layer with P-type impurities.

The first metal layer 55A exists only in the gate electrode 201 of the cell region, and may include a TiN layer. The first metal layer 55A has a thin thickness of approximately 30 Å to approximately 150 Å.

Though not shown, junctions doped with impurities can be formed in portions of the substrate corresponding to the respective transistors. For example, source/drain junction doped with N-type impurities is formed in portions of the substrate corresponding to the cell nMOS region and the peripheral circuit nMOS region, and a source/drain junction doped with P-type impurities is formed in a portion of the substrate corresponding to the peripheral circuit pMOS region. Also, gate sidewall spacers and an LDD structure can be further formed.

In accordance with the foregoing, a transistor formed in the cell nMOS region becomes a fin FET by the fin structure 53, and transistors formed in the peripheral nMOS region and pMOS region become planar FETs.

Particularly, since a material directly contacting the gate insulation layer 54 is the first metal layer 55A in the gate electrode 201 in the cell nMOS region, the threshold voltage of the transistor formed in the cell nMOS region is dominated by the first metal layer 55A. For example, the work function of the first metal layer 55A is in the range of approximately 4.4 eV to approximately 4.8 eV, which is greater than the work functions (4 eV) of the N-type polysilicon layers 57B and 57C and smaller than the work function (5 eV) of the P-type polysilicon layer 57D. That is, the first metal layer 55A has a mid work function.

Therefore, since the work function of the first metal layer 55A is smaller than that of the P-type polysilicon layer, a band bending does not occur excessively, and thus GIDL is reduced. Also, since the work function of the thin first metal layer 55A is greater than that of the N-type polysilicon layer, the threshold voltage of the transistor can be increased to a predetermined level or more.

Consequently, the first metal layer 55A with a smaller work function than that of the P-type polysilicon layer is allowed to contact the gate insulation layer 54 and thus to be included in the gate electrode 201 for the transistor formed in the cell region (i.e., the cell transistor), so that a high threshold voltage is obtained to reduce off-leakage, and simultaneously, a band bending at a junction interface with the gate insulation layer 54 can be smoothed.

Also, a multi-plane channel such as the fin structure 53 is used to increase a channel length, so that current drivability can be improved.

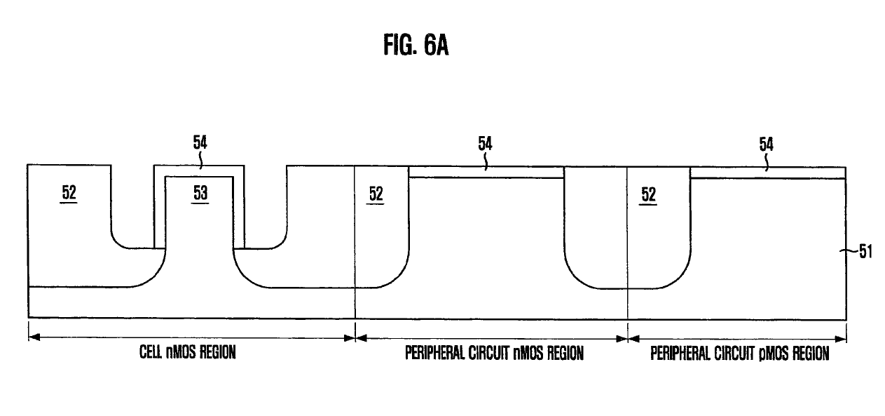

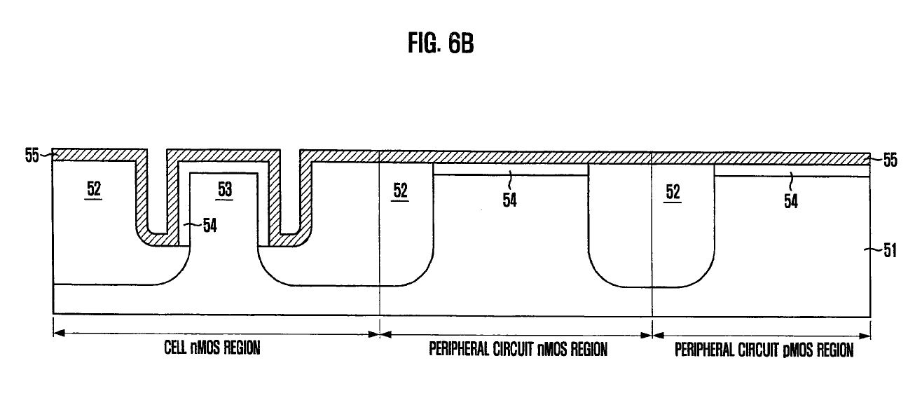

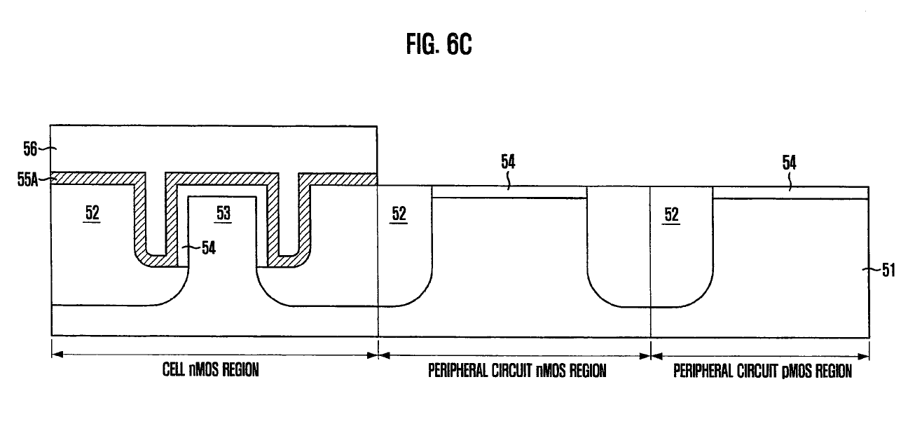

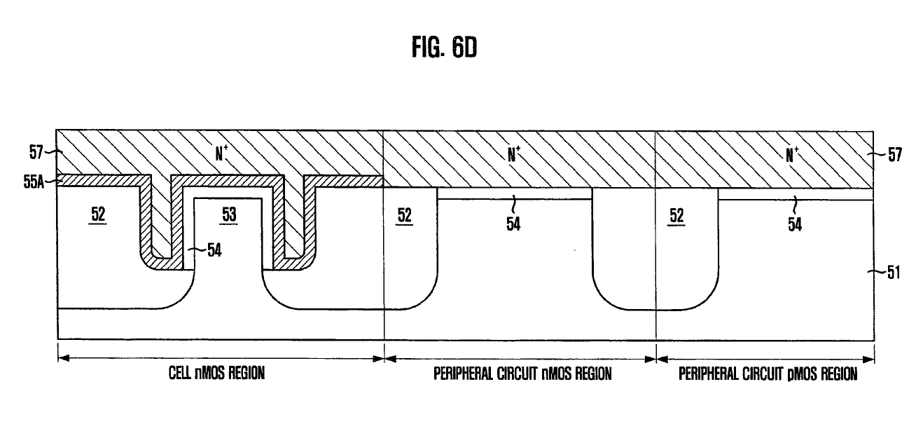

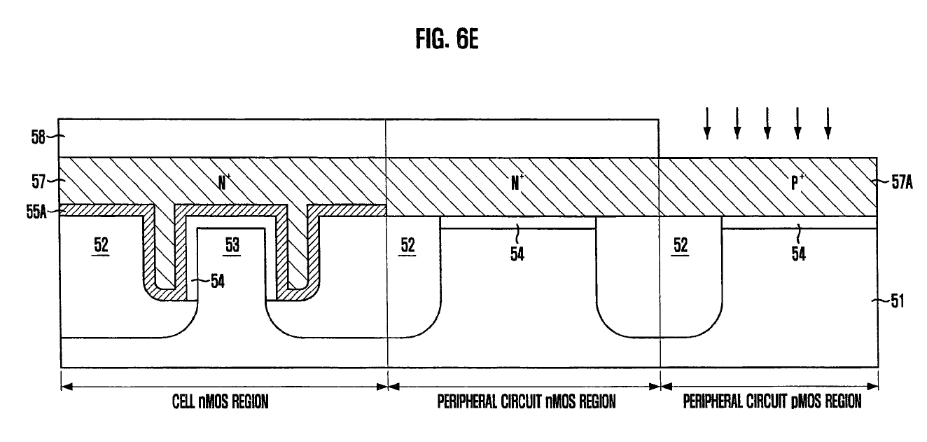

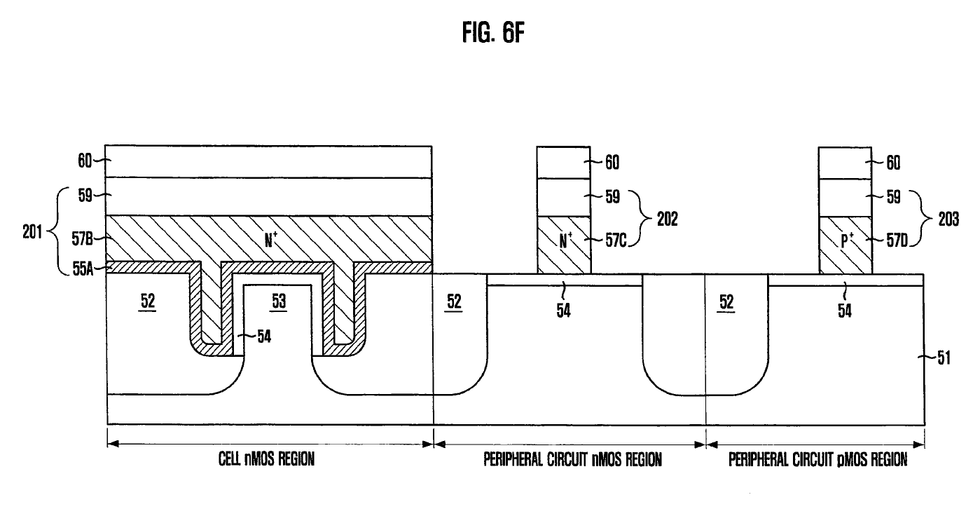

FIGS. 6A to 6F illustrate cross-sectional views explaining a method for manufacturing a memory device illustrated in FIG. 5.

Referring to FIG. 6A, a device isolation layer 52 for isolation between respective regions is formed in a substrate 51. At this point, the substrate 51 is divided into a cell region and a peripheral circuit region. The peripheral circuit region is divided into an nMOS region and a pMOS region. Meanwhile, a cell region is an nMOS region where an nMOS is to be formed. Hereinafter, the cell region is called a ‘cell nMOS region’, the nMOS region in the peripheral circuit region is called a ‘peripheral circuit nMOS region’, and the pMOS region in the peripheral circuit region is called a ‘peripheral circuit pMOS region’.

Next, a fin structure 53 is formed in a portion of the substrate 51 corresponding to the cell nMOS region. At this point, the fin structure 53 is formed by selectively recessing the device isolation layer 52. The fin structure 53 is a type of multi-plane channel for increasing a channel length.

A gate insulation layer 54 is formed over the substrate 51.

Referring to FIG. 6B, the first metal layer 55 is formed over the gate insulation layer 54. At this point, the first metal layer 55 is a material included in a gate electrode and can include a TiN layer. Also, the first metal layer 55 has a thin thickness of approximately 30 Å to approximately 150 Å and has a uniform thickness over the substrate.

Referring to FIG. 6C, a first photoresist pattern 56 is formed over the first metal layer 55. At this point, the first photoresist pattern 56 covers the cell nMOS region and open over the peripheral circuit regions.

The first metal layer 55 is etched using the first photoresist pattern 56 as an etch barrier. By doing so, the first metal layer 55 is left over only a portion of the substrate 51 corresponding to the cell nMOS region.

Referring to FIG. 6D, after the first photoresist pattern 56 is removed, a polysilicon layer is deposited over the substrate. At this point, the polysilicon layer can be doped with N-type impurities or P-type impurities in In-Situ. Therefore, the polysilicon layer becomes an N-type polysilicon layer or a P-type polysilicon layer. Hereinafter, it is assumed that the polysilicon layer is an N⁺ polysilicon layer 57 heavily doped with N-type impurities.

Also, the N-type polysilicon layer 57 has a thickness that gap-fills all of the height differences generated by the fin structure 53 formed in the cell nMOS region. For example, the N-type polysilicon layer 57 is deposited to a thickness of approximately 500 Å to approximately 1000 Å.

Referring to FIG. 6E, a second photoresist pattern 58 is formed over the N-type polysilicon layer 57. At this point, the second photoresist pattern covers the cell nMOS region and the peripheral circuit nMOS region, and open over the peripheral circuit pMOS region.

An ion implantation is performed using the second photoresist pattern 58 as an ion implantation barrier. At this point, the ion implantation is performed by implanting P-type impurities at a high concentration (which is denoted by P⁺). This is for counter-doping the N-type polysilicon layer with P-type impurities. Therefore, the N-type polysilicon layer in the peripheral circuit pMOS region becomes a P-type polysilicon layer by the ion implantation.

Referring to FIG. 6F, after the second photoresist pattern 58 is removed, a gate patterning is performed to complete a gate structure over each region.

A resulting structure of the gate patterning is described. A gate electrode 201 in the cell nMOS region includes the first metal layer 55A and an N-type polysilicon layer 57B. A gate electrode 202 in the peripheral circuit nMOS region includes an N-type polysilicon layer 57C. A gate electrode 203 in the peripheral circuit pMOS region includes a P-type polysilicon layer 57D. Meanwhile, the gate electrode in each region further includes a second metal layer 59 in an uppermost layer. A gate hard mask layer 60 can be further formed over each gate electrode. The second metal layer 59 is a low resistance metal layer and is used to reduce the sheet resistance of the gate electrode. For example, the second metal layer 59 can be a tungsten layer or a tungsten silicide layer. Also, the gate hard mask layer 60 includes a nitride layer.

Though not shown, impurities are implanted to be suitable for the characteristic of the transistor in each region to form a source junction and a drain junction. An N-type source junction and an N-type drain junction are formed in the nMOS region, and a P-type source junction and a P-type drain junction are formed in the pMOS region. Also, an LDD structure can be further formed using gate sidewall spacers.

In accordance with the above-described manufacturing method, the gate electrode 201 formed over the gate insulation layer 54 includes the first metal layer 55A and the N-type polysilicon layer 57B each have a different work function in the cell nMOS region.

As described, though the N-type polysilicon layer 57B exists over the first metal layer 55A in the gate electrode 201 of the cell nMOS region, the first metal layer 55A directly contacts the gate insulation layer 54, so that the threshold voltage of the transistor is dominated by the work function of the first metal layer 55A. Since the work function of the first metal layer 55A is smaller than that of the P-type polysilicon layer, a band bending does not occur excessively and thus the GIDL is reduced. Also, since the work function of the thin first metal layer 55A is greater than that of the N-type polysilicon layer, the threshold voltage of the transistor can be increased to a predetermined level or more.

Consequently, the first metal layer 55A having a smaller work function than that of the P-type polysilicon layer is allowed to contact the gate insulation layer 54 and thus to be included in the gate electrode 201, so that a high threshold voltage is obtained to reduce off-leakage, and simultaneously, a band bending at a junction interface with the gate insulation layer 54 can be smoothed.

Also, a multi-plane channel such as the fin structure 53 is used to increase a channel length, so that current drivability can be improved.

In accordance with the present invention, a metal layer having a smaller work function than that of a P-type polysilicon layer is allowed to contact a gate insulation layer in a gate electrode of a transistor formed in a cell region, so that a high threshold voltage is obtained and thus off-leakage is reduced, and simultaneously a band bending at a junction interface with the gate insulation layer is smoothed, so that a gate induced drain leakage characteristic can be reduced.

Also, a multi-plane channel such as a fin structure is applied to a transistor formed in a cell region, so that a channel length is increased and thus current drivability can be improved.

While the present invention has been described with respect to the specific embodiments, it will be apparent to those skilled in the art that various changes and modifications may be made without departing from the spirit and scope of the invention as defined in the following claims.

What is claimed is:

1. A transistor, comprising:
a gate insulation layer over a substrate;
a gate line comprising electrodes each having a different work function on the gate insulation layer; and
a source junction and a drain junction formed inside portions of the substrate on first and second sides of the gate line.

2. The transistor of claim 1, wherein one of the electrodes forming the gate line contacting the gate insulation layer comprises a material having a work function greater than that of a polysilicon layer doped with N-type impurities and smaller than that of a polysilicon layer doped with P-type impurities.

3. The transistor of claim 1, wherein one of the electrodes forming the gate line contacting the gate insulation layer has a work function in a range of 4.4 eV to 4.8 eV.

4. The transistor of claim 1, wherein the gate line comprises a metal layer contacting the gate insulation layer and a polysilicon layer provided on the metal layer.

5. The transistor of claim 4, wherein the metal layer comprises a TiN layer.

6. The transistor of claim 4, wherein the polysilicon layer comprises a polysilicon layer doped with impurities.

7. The transistor of claim 6, wherein the impurities comprise N-type impurities.

8. The transistor of claim 4, further comprising a low resistance metal layer on the polysilicon layer.

9. The transistor of claim 8, wherein the low resistance metal layer comprises one of a tungsten layer and a tungsten silicide layer.

10. The transistor of claim 1, further comprising a multi-plane channel structure formed in a portion of the substrate under the gate electrode.

11. The transistor of claim 10, wherein the multi-plane channel structure comprises one of a fin, a recess, a bulb type recess, and a saddle fin structure.

12. A memory device, comprising:
a substrate comprising a cell region and a peripheral circuit region;
a gate insulation layer on the substrate;
a first gate electrode formed over a portion of the gate insulation layer corresponding to the cell region; and
a second gate electrode formed over a portion of the gate insulation layer corresponding to the peripheral circuit region, the first gate electrode comprising electrodes each having a different work function.

13. The memory device of claim 12, wherein one of the electrodes of the first gate electrode that contacts the gate insulation layer comprises a material having a work function greater than that of a polysilicon layer doped with N-type impurities and smaller than that of a polysilicon layer doped with P-type impurities.

14. The memory device of claim 12, wherein one of the electrodes of the first gate electrode contacting the gate insulation layer has a work function in a range of 4.4 eV to 4.8 eV.

15. The memory device of claim 12, wherein the first gate electrode comprises a metal layer contacting the gate insulation layer and a polysilicon layer on the metal layer.

16. The memory device of claim 15, wherein the metal layer comprises a TiN layer.

17. The memory device of claim 15, wherein the polysilicon layer comprises a polysilicon layer doped with N-type impurities.

18. The memory device of claim 15, further comprising a low resistance metal layer on the polysilicon layer.

19. The memory device of claim 18, wherein the low resistance metal layer comprises one of a tungsten layer and a tungsten silicide layer.

20. The memory device of claim 12, further comprising a multi-plane channel structure comprising one of a fin, a recess, a bulb type recess, and a saddle fin structure in a portion of the substrate under the first gate electrode.

21. The memory device of claim 12, wherein the second gate electrode has a stacked structure of a polysilicon layer and a low resistance metal layer.

22. The memory device of claim 21, wherein the polysilicon layer comprises a polysilicon layer doped with N-type impurities or P-type impurities.

23. The memory device of claim 12, wherein the first gate electrode comprises a gate electrode of a transistor having a multi-plane channel, and the second gate electrode comprises a gate electrode of a transistor having a planar channel.

24. The memory device of claim 12, wherein the first gate electrode comprises a gate electrode of a fin field effect transistor (FET), and the second gate electrode comprises a gate electrode of a planar FET.

25. The memory device of claim 24, wherein the fin FET comprises an nMOS transistor, and the planar FET comprises one of an nMOS transistor and a pMOS transistor.
